(19) United States
(12) Patent Application Publication
(10) Pub. No.: US 2010/0323160 A1
(43) Pub. Date: Dec. 23, 2010

(54) ZnO-BASED THIN FILM

(75) Inventors: Ken Nakahara, Kyoto (JP); Hiroyuki Yuji, Kyoto (JP); Kentaro Tamura, Kyoto (JP); Shunsuke Akasaka, Kyoto (JP); Masashi Kawasaki, Sendai-shi (JP); Akira Ohtomo, Sendai-shi (JP); Atsushi Tsukazaki, Sendai-shi (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/526,113

(22) PCT Filed: Feb. 6, 2008
(86) PCT No.: PCT/JP2008/051927

§ 371 Date: Aug. 6, 2009

(30) Foreign Application Priority Data
Feb. 6, 2007 (JP) P2007-027182
Jan. 15, 2008 (JP) P2008-005987

(51) Int. Cl. B32B 33/00; C30B 29/16; B32B 9/00

(52) U.S. Cl. 428/141; 428/172; 428/167

(57) ABSTRACT

Provided is a ZnO-based thin film for growing a flat film when the ZnO-based thin film is formed on a substrate. In FIG. 1(a), a ZnO-based film 2 is formed on a ZnO-based substrate 1. Meanwhile, in FIG. 1(b), a ZnO-based laminated body 10 that is a laminated body of ZnO-based thin films is formed on the ZnO-based substrate 1. The ZnO-based laminated body 10 is the laminated body in which multiple ZnO-based thin films including a ZnO-based thin film 3, a ZnO-based thin film 4 and the like are laminated. When forming the ZnO-based thin film 2 or the ZnO-based laminated body 10, the film or the body is formed at a growth temperature of 750° C. or above, or alternatively, a step structure on a surface of the film is formed into a predetermined structure such that roughness on the surface of the film is in a predetermined range.

### TECHNICAL FIELD

The present invention relates to a ZnO-based thin film to be epitaxially grown on a substrate.

### BACKGROUND ART

There are growing expectations for application of ZnO-based semiconductor to ultraviolet LEDs used as light sources for illuminations and backlights, high-speed electronic devices, surface acoustic wave devices, and the like. Despite the attention to its multifunctionality as well as huge light emission potential, the ZnO-based semiconductor has not been successfully developed as a semiconductor device material. The largest obstacle is that a p-type ZnO has not been successfully obtained because of a difficulty in acceptor doping.

However, in recent years, as Non-patent Document 1 and Non-patent Document 2 shows, the technological advancements have made it possible to obtain a p-type ZnO and further to achieve light emission using the p-type ZnO. Semiconductor devices often have specific functions obtained by depositing thin films with different dopants, thin films with different compositions, and the like. In that case, flatness of those thin films is an important issue.

Poor flatness of a thin film may incur resistance for carriers to move through inside the thin film, or an increase in surface roughness on an upper layer of a laminated structure. Problems such as a failure to achieve uniformity of etching depth due to the surface roughness or anisotropic growth of a crystal plane due to the surface roughness are apt to occur, and may make it difficult for a semiconductor device to exhibit desired functions. Accordingly, it is usually desirable to form the surface of the thin film as flat as possible.

Meanwhile, ZnO is often used to be grown on a sapphire substrate, as is manufactured a GaN-based semiconductor element. However, as a ZnO crystal substrate becomes commercially available, there have been attempts to grow a ZnO-based thin film on a ZnO-based substrate.

### Non-patent Document 1: A. Tsukazaki et al., JJAP44 (2005) L643

### Non-patent Document 2: A. Tsukazaki et al., Nature Materials (2005) 42

### DISCLOSURE OF THE INVENTION

### Problem to be Solved by the Invention

Although growth of a ZnO-based thin film on a substrate for growth such as a ZnO-based substrate seems very easy, it is actually difficult to obtain surface flatness in a wide area. Conditions and the like for obtaining the uniform surface flatness, such as which type of ZnO-based thin film is supposed to be used, have not yet been clarified.

The present invention has been made to solve the above-mentioned problem, and an object thereof is to provide a ZnO-based thin film for growing a flat film when a ZnO-based film is formed on a substrate.

### Means for Solving the Problem

To attain the object, the invention according to a first aspect provides a ZnO-based thin film to be epitaxially grown on a substrate, which is characterized in that a principal surface in a direction of crystal growth of the ZnO-based thin film is formed to have an arithmetic average roughness of 1.5 nm or below and a square mean roughness of 2 nm or below.

Meanwhile, the invention according to a second aspect provides a ZnO-based thin film to be epitaxially grown on a substrate, which is characterized in that a principal surface in a direction of crystal growth of the ZnO-based thin film is formed to have an arithmetic average roughness of 1 nm or below and a square mean roughness of 1.5 nm or below.

Meanwhile, the invention according to a third aspect provides a ZnO-based thin film to be epitaxially grown on a substrate, which is characterized in that a step height of a surface step structure included in a principal surface in a direction of crystal growth of the ZnO-based thin film is formed to be equivalent to one monolayer thickness of a ZnO-based crystal.

Meanwhile, the invention according to a fourth aspect provides a ZnO-based thin film to be epitaxially grown on a substrate, which is characterized in that step lines of a surface step structure included in a principal surface in a direction of crystal growth of the ZnO-based thin film are formed substantially perpendicularly to an m-axis.

Meanwhile, the invention according to a fifth aspect provides the ZnO-based thin film according to the first and second aspects of the invention, which is characterized in that the principal surface in the direction of the crystal growth includes a surface step structure and a step height of the step structure is formed to be equivalent to one monolayer thickness of a ZnO-based crystal.

Meanwhile, the invention according to a sixth aspect provides the ZnO-based thin film according to any of the first, second and third aspects of the invention, which is characterized in that the principal surface in the direction of the crystal growth includes a surface step structure, and step lines of the step structure are formed substantially perpendicularly to an m-axis.

Meanwhile, the invention according to a seventh aspect provides the ZnO-based thin film according to either of the fourth and sixth aspects of the invention, which is characterized in that a fluctuation range of irregularities from straightness of the step lines is formed to be equal to or below an ideal width of a terrace surface included in the step structure relative to almost all of the step lines.

Meanwhile, the invention according to an eighth aspect provides a ZnO-based thin film characterized by being epitaxially grown on a substrate at a growth temperature of 750° C. or above. Meanwhile, the invention according to a ninth aspect provides the ZnO-based thin film according the sixth aspect of the invention, which is characterized in that a fluctuation range of irregularities from straightness of the step lines is formed to be equal to or below an ideal width of a terrace surface included in the step structure relative to almost all of the step lines.

### EFFECT OF THE INVENTION

According to the present invention when a ZnO-based film is epitaxially grown on a substrate, it is possible to obtain a flat film as a growth temperature (a substrate temperature) is set at 750° C. or above. Moreover, the conditions equivalent to the case of setting the growth temperature at 750° C. or above, i.e. the conditions of the roughness on the crystal growth surface and of the step structure on the crystal growth surface are defined so that it is possible not only to obtain the flat ZnO-based thin film but also to maintain film flatness of a ZnO-based film laminated on an upper layer even when such a ZnO-based thin film is further laminated repeatedly on the ZnO-based thin film. Furthermore, the step is apt to be stabilized in the course of step flow growth so that the flat surface can be easily obtained.

### BRIEF DESCRIPTION OF THE DRAWINGS

FIG. 1 is a view showing a laminated structure of a ZnO-based thin film of the present invention.

FIG. 2 is a view showing states of surfaces of the ZnO-based thin film of the present invention in various growth temperatures.

FIG. 3 is a view showing a state of a surface when laminating multiple layers of the ZnO-based thin film of the present invention.

FIG. 4 is a view showing a relation between arithmetic average roughness of a surface of a ZnO-based thin film and a substrate temperature.

FIG. 5 is a view showing a relation between square mean roughness of a surface of a ZnO-based thin film and a substrate temperature.

FIG. 6 is a view for explaining the arithmetic average roughness and the square mean roughness.

FIG. 7 is a view for explaining relations among a normal line to a principal surface of a substrate and a c-axis, an m-axis, and an a-axis which are crystal axes of the substrate.

FIG. 8 is a view showing a substrate surface when the normal line to the principal surface of the substrate has an miscut angle only in a direction of the m-axis.

FIG. 9 is a view showing a state of arrangement of step lines having some irregularities in the direction of the m-axis.

FIG. 10 is a view showing a configuration to measure a substrate temperature when growing the ZnO-based thin film.

FIG. 11 is a view showing another configuration to measure the substrate temperature when growing the ZnO-based thin film.

### BEST MODES FOR CARRYING OUT THE INVENTION

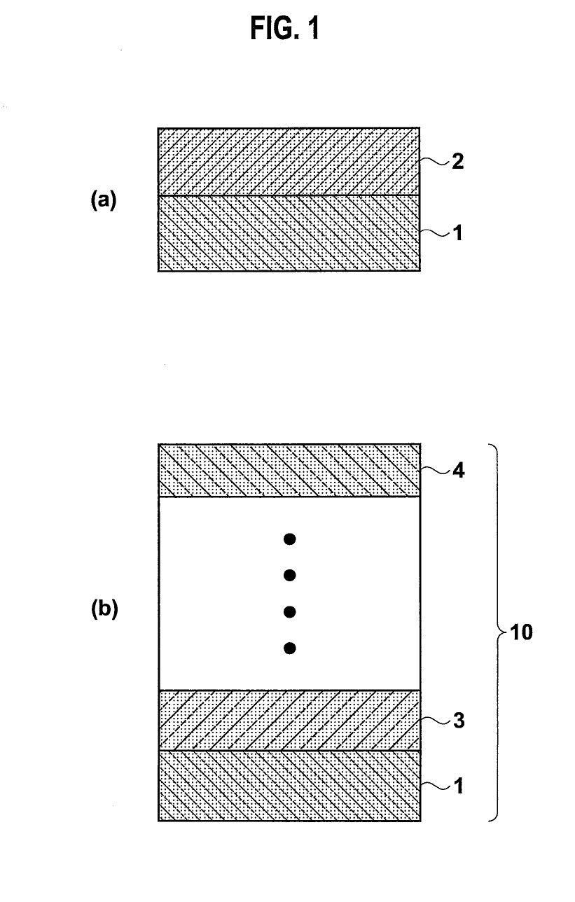

Now, an embodiment of the present invention will be described below with reference to the accompanying drawings. FIG. 1 shows a structure of a ZnO-based thin film of the present invention.

Here, a ZnO base in a ZnO-based thin film is a alloyed crystal material based on ZnO including, one in which Zn is partially replaced with a IIA group element or a IIB group element, one in which O is partially replaced with a VIB group element, and a combination of both of them.

In FIG. 1(a), a ZnO-based film 2 that is a ZnO-based material layer is formed on a ZnO-based substrate 1 that is another ZnO-based material layer. Meanwhile, in FIG. 1(b), a ZnO-based laminated body 10 that is a laminated body of ZnO-based thin films being ZnO-based material layers is formed on the ZnO-based substrate 1 that is the ZnO-based material layer. The ZnO-based laminated body 10 is the laminated body in which multiple ZnO-based thin layers including a ZnO-based thin film 3 and a ZnO-based thin film 4 are laminated.

As described above, when the ZnO-based thin film is epitaxially grown on the ZnO-based material layer, an important point is that the epitaxially grown ZnO-based thin film constitutes a substrate so that flatness of films is achievable on upper layers which are repeatedly laminated on the substrate. Conditions that can achieve the flat ZnO-based thin films in any cases of FIGS. 1(a) and 1(b) will be described below.

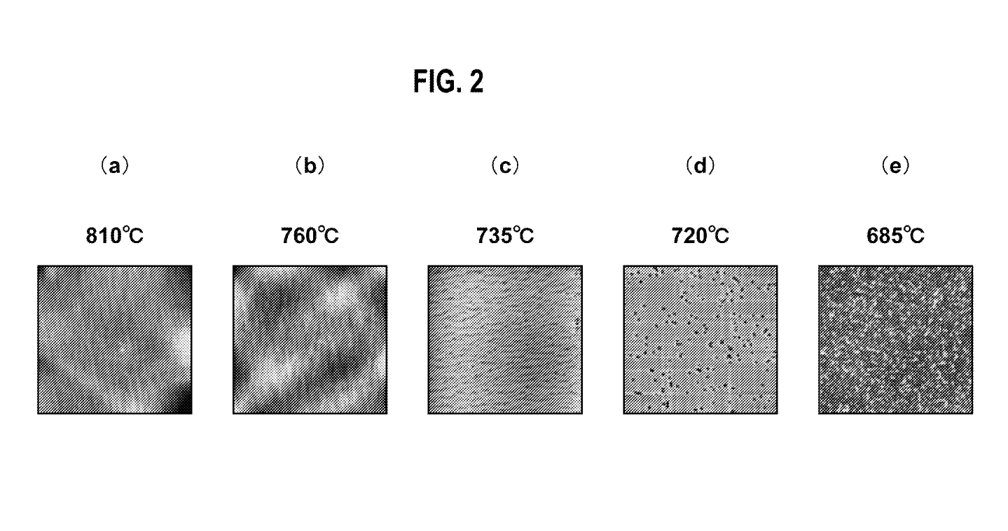

FIG. 2 shows surface images when the ZnO-based thin film 2 is epitaxially grown on the ZnO-based substrate 1 using an MBE (molecular beam epitaxy) method as shown in FIG. 1(a). To be more precise, ZnO is applied to the ZnO-based substrate 1 while ZnO is applied to the ZnO-based thin film 2. FIG. 2 represents the surface images of the grown ZnO, which are scanned in a 20 μm square area by using an atomic force microscope (AFM).

Measurements are executed while changing the substrate temperature in the case of causing the crystal growth of ZnO. As shown in FIG. 2, FIG. 2(a) represents 810° C., FIG. 2(b) represents 760° C., FIG. 2(c) represents 735° C., FIG. 2(d) represents 720° C., and FIG. 2(e) represents 685° C. In the cases of FIGS. 2(c), 2(d), and 2(e), irregularities of surface flatness are conspicuous as apparent from the surface images in the drawings. Meanwhile, in the cases of FIGS. 2(a) and 2(b), it is apparent that the surfaces are in nice conditions and the flatness of the films is in good states.

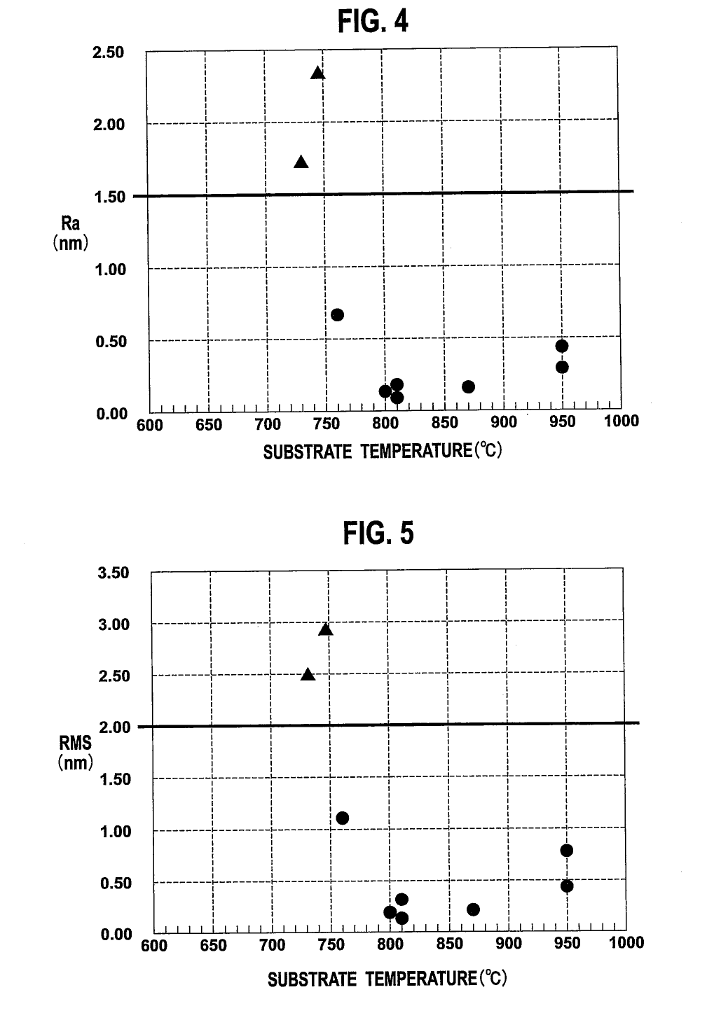

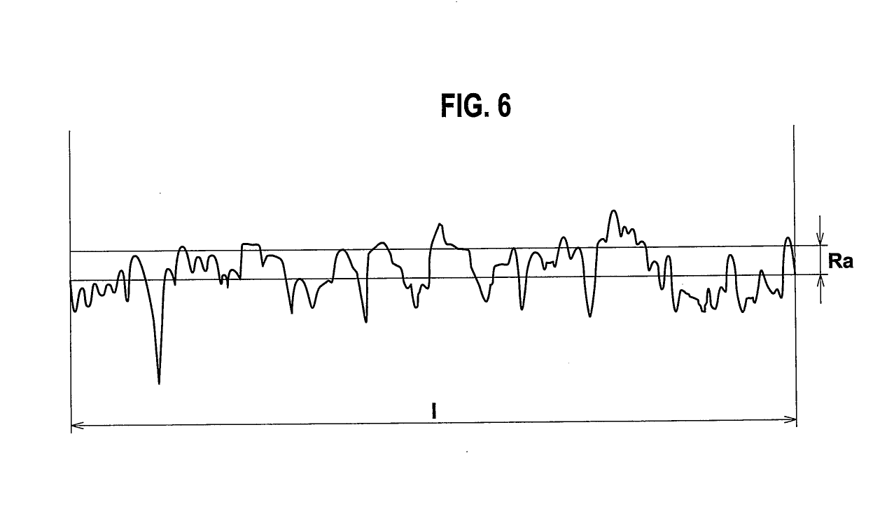

Next, the substrate temperature is changed more finely than the temperatures illustrated in FIG. 2 and the flatness of the ZnO surface at that time is expressed in numerical values. FIG. 4 is a graph showing those values. The longitudinal axis Ra (in the unit of nm) of FIG. 4 shows arithmetic average roughness of the film surface. The arithmetic average roughness Ra is derived from a measured roughness curve as shown in FIG. 6.

The roughness curve is obtained by measuring the irregularities on the film surfaces observed in FIG. 2, for example, at predetermined sampling points and showing sizes of the irregularities together with average values of the irregularities. Moreover, a reference length l is extracted from the roughness curve in a direction of an average line thereof and an average value is obtained by summing up absolute values of deviations from the average line of the extracted portion to a measurement curve. The arithmetic average roughness is expressed as Ra=(1/1)×∫|f(x)|dx (an integral interval ranges from 0 to 1). By executing this, an influence of a single scratch on the measured value becomes extremely small so that a stable result can be obtained. Here, parameters of the surface roughness such as the arithmetic average roughness Ra are defined by the JIS standard, which are applied hereto.

FIG. 4 displays the arithmetic average roughness Ra thus calculated along the longitudinal axis and displays the substrate temperature along the lateral axis. Black triangles (▴) in FIG. 4 indicate data when the substrate temperature is below 750° C., while black circles () indicate data when the substrate temperature is at 750° C. or above. As apparent from FIG. 4, the flatness of the surface is significantly improved when the substrate temperature becomes higher than a boundary of the substrate temperature of 750° C. Moreover, it is apparent that a boundary value of the arithmetic average roughness Ra in this case becomes equal to 1.5 nm when Ra is loosely determined or about equal to 1.0 nm when Ra is strictly determined.

FIG. 5 shows square mean roughness RMS of the film surface derived from the same measurement data as those in FIG. 4. The square mean roughness RMS represents a square root of a value obtained by summing up square values of deviations from the average line of the measured roughness curve to the measurement curve as shown in FIG. 6 and then averaging those values. Using the reference length l to calculate the arithmetic average roughness Ra, the following equation is obtained:

RMS={(1/l)×∫(f(x))²dx}^{1/2} (an integral interval ranges from 0 to l).

FIG. 5 shows the square means roughness RMS along the longitudinal axis and the substrate temperature along the lateral axis. Here, black triangles (▴) indicate data when the substrate temperature is below 750° C., while black circles () indicate data when the substrate temperature is at 750° C. or above. In terms of the substrate temperature, it is apparent as in FIG. 4 that the flatness of the surface is significantly improved at the boundary of 750° C. Meanwhile, in terms of the square mean roughness RMS, it is apparent that a boundary value becomes equal to 2.0 nm when loosely determined or about equal to 1.5 nm when strictly determined.

Therefore, when the ZnO-based thin film is grown on the ZnO-based material layer, the film having the fine flatness is obtained by carrying out the epitaxial growth with the substrate temperature of 750° C. or above. Meanwhile, from the viewpoint of the surface roughness, it is possible to maintain the flatness of the ZnO-based thin films to be laminated later by conducting the crystal growth on a growing surface (a principal surface) so as to achieve the arithmetic average surface roughness Ra equal to or below 1.5 nm and the square mean roughness RMS equal to or below 2.0 nm. It is more desirable to conduct the crystal growth so as to achieve Ra equal to or below 1 nm and RMS equal to or below 1.5 nm.

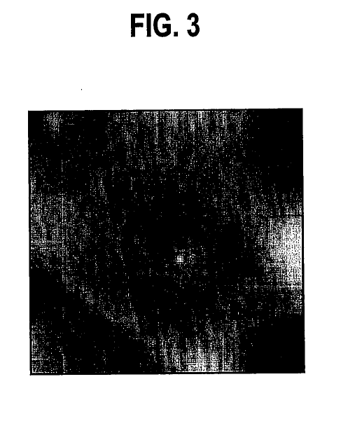

For example, FIG. 3 shows a surface image when the ZnO-based thin films are laminated, under the above-described conditions, as in FIG. 1(b). This is, as in FIG. 2, the image scanned in a 20 μm square by using atomic force microscope (AFM). To be more precise, ZnO is applied to the ZnO-based substrate 1 while the ZnO-based laminated body 10 is formed thereon by alternately laminating Mg_{0.1}ZnO and ZnO for ten cycles. The substrate temperature is set to 770° C. In the case of laminating not only the ZnO thin film on the ZnO thin film but also laminating the mixed crystal composition thin films as shown in FIG. 3, it is apparent that the flat film can be obtained on the uppermost layer of the laminated structure by setting the proper substrate temperature or maintaining the constant surface roughness.

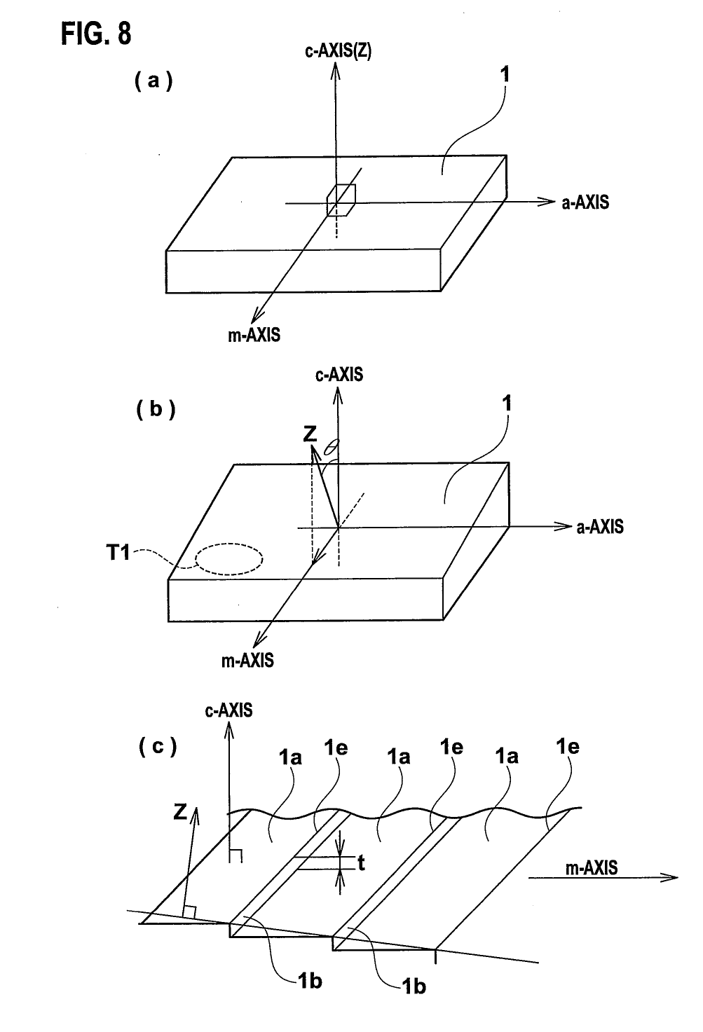

Next, conditions for forming the film flatness will be considered in light of a crystal structure of a ZnO-based compound. As in the case of GaN, the ZnO-based compound has a hexagonal crystal structure which is called wurtzite. Expressions such as a C-plane or an a-axis can be defined by using so-called the Miller index. For example, the C-plane is expressed as a (0001) plane. When growing the ZnO-based thin film on the ZnO-based material layer, the C-plane or the (0001) plane is usually utilized. However, when an exact C-plane substrate is used, a direction of normal line to a principal surface of a wafer coincides with a direction of the c-axis as shown in FIG. 8(a). Nevertheless, it is known that the film flatness is not improved by growing the ZnO-based thin film on the exact C-plane substrate.

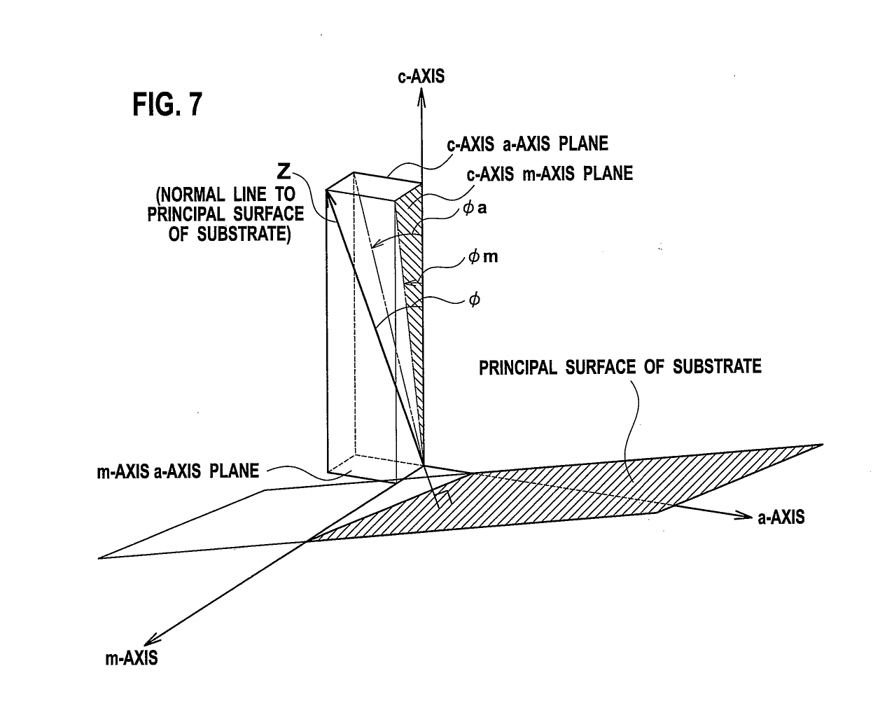

Accordingly, as shown in FIG. 7, the ZnO-based substrate 1 is polished such that the normal line to the principal surface of the substrate having a +C-plane is inclined relative to the c-axis and that the principal surface of the substrate has the normal line which is at least inclined in the direction of the m-axis from the c-axis. FIG. 7 shows a case in which a normal line Z to the principal surface of the substrate is inclined at an angle Φ from the c-axis of the substrate crystal axis, and a projection axis defined by projecting the normal line Z onto a c-axis m-axis plane in an orthogonal coordinate system utilizing the substrate crystal axes of the c-axis, the m-axis, and the a-axis is inclined at an angle Φₘ toward the m-axis, while a projection axis defined by projecting the normal line Z onto a c-axis a-axis plane is inclined at an angle Φₐ toward the a-axis.

That is, the normal line Z to the principal surface of the substrate is allowed to be inclined relative to the c-axis of the substrate crystal axis so as to define a miscut angle without coincidence of the direction of the c-axis with the direction of the normal line to the principal surface of the ZnO-based substrate 1 (the wafer). For example, as shown in FIG. 8(b), the normal line Z to the principal surface is assumed to exist on the c-axis m-axis plane, and the normal line Z is assumed to be inclined by θ degrees from the c-axis only in the direction of the m-axis. Then, terrace surfaces 1a having flat surfaces and step surfaces 1b formed regularly and at an even interval at step portions defined by the inclination of the normal line Z are produced as shown in FIG. 8(c), which is an enlarged view of a surface portion (such as a T1 region) of the substrate 1.

Here, the terrace surface 1a becomes the C-plane (0001) and the step surface 1b corresponds to an M-plane (10-10). As shown in the drawing, the respective step surfaces 1b ideally formed are arranged regularly while maintaining the same width of the terrace surfaces 1a in the direction of the m-axis. Specifically, the c-axis that is perpendicular to the terrace surface 1a and the normal line Z to the principal surface of the substrate define the miscut angle of θ degrees. Meanwhile, step lines 1e serving as step edges of the step surfaces 1b are arranged in parallel while maintaining a perpendicular relation with the direction of the m-axis and defining the widths of the terrace surfaces 1a.

As described above, by defining the step surfaces as surfaces corresponding to the M-plane, it is possible to form the flat film on a ZnO-based semiconductor layer which is epitaxially grown on the principal surface. A step portion is generated on the principal surface by the step surface 1b. However, atoms that come usually from its gas phase to this step portion are bonded with two surfaces of the terrace surface 1a and the step surface 1b, thereby achieving stronger bonding than a case of flying onto the terrace surface 1a. Hence it is possible to trap the flying atoms stably.

While the flying atoms are diffused in the terrace in a surface diffusion process, stable growth is executed by way of lateral growth in which the flying atoms are trapped by the step portion having the strong bonding force or by a kink position formed at this step portion and are incorporated into a crystal. In this way, when the ZnO-based semiconductor layer is laminated on the substrate having the normal line to the principal surface of the substrate which is inclined at least in the direction of the m-axis, the ZnO-based semiconductor layer causes crystal growth mainly on this step surface 1b. Hence it is possible to form the flat film.

Incidentally, if the inclined angle (the miscut angle) θ is set too large in FIG. 8(b), a step height t of the step surface 1b becomes too large and it is impossible to achieve the flat crystal growth. Accordingly, the miscut angle θ in the direction of the m-axis is set at 0.5 degrees in a manufacturing example to be described below. When this inclined angle is adopted, the step height t equivalent to one monolayer of the ZnO-based crystal is easily obtained.

As described above, it is essential to arrange the step lines 1e regularly in the direction of the m-axis and to establish the perpendicular relation between the direction of the m-axis and the step lines 1e for fabricating the flat film. If the intervals or the lines of the step lines 1e fluctuate, the above-described lateral growth does not take place. Accordingly, it is impossible to fabricate the flat film.

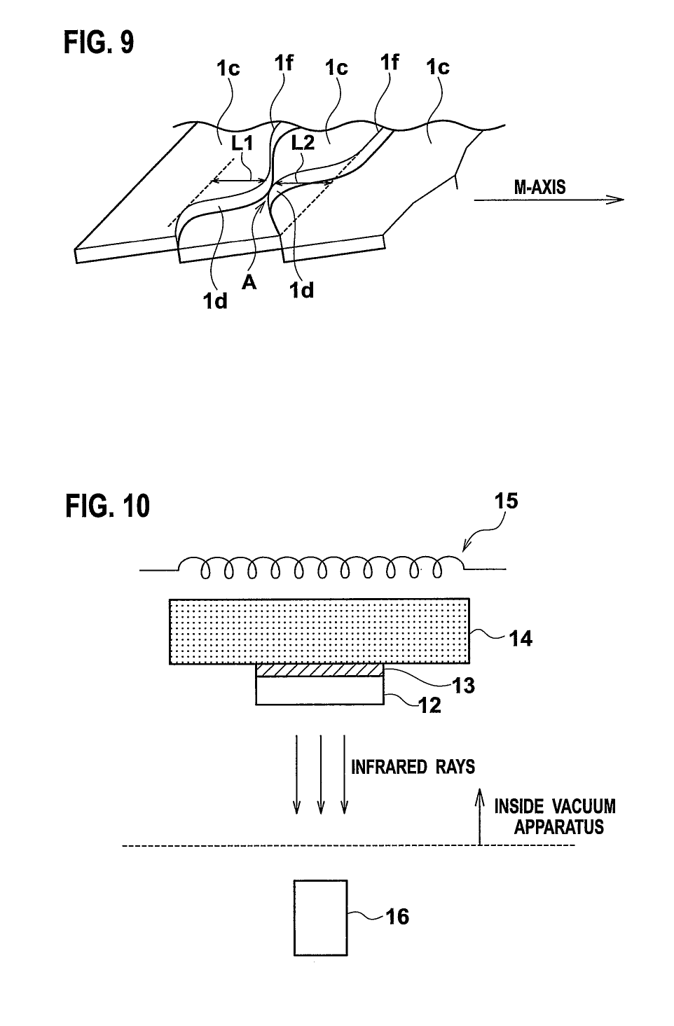

The perpendicularity of the step lines 1e to them-axis also includes a case where the step surfaces 1d are not always flat but provided with some irregularities (waves) as shown in FIG. 9, for example. Fluctuation ranges from peaks to peaks of the irregularities existing on step lines 1f may include various different fluctuation ranges such as L1 or L2 as shown in the drawing. When these fluctuation ranges are collectively referred to as L while an ideal width of a terrace surface 1c is defined as W, almost all the steps need to satisfy L≦W in order to fabricate the flat film. Here, the ideal width W of the terrace surface 1c is expressed as W=t/tan θ by using the above-described miscut angle θ (radian) and the step height t.

While the fluctuation ranges L includes multiple fluctuation ranges having L1 and L2 as described above, it is preferable that the above-described inequality expression be applied to step structure in which almost all the multiple fluctuation ranges satisfy L≦W. When the fluctuation ranges do not satisfy L≦W, the step lines are bundled as shown in a portion A in FIG. 9 and a gap of the step becomes larger, thereby causing fluctuation in a lateral growth rate, which may incur surface roughness. For example, when the step height t is set to 0.26 nm corresponding to a single molecular layer of the ZnO-based crystal and the miscut angle θ is set to 0.5 degrees, W=t/tan θ becomes approximately equal to 30 nm. Here, perpendicularity of the step line 1f including the irregularities with respect to the m-axis may be determined by regarding a center line of the irregularities as the step line.

As described above, it is possible to form the ZnO-based thin film having the flat surface so as to maintain the step structure on the surface of the ZnO-based crystal growth. Moreover, it is also possible form the flat ZnO-based thin films to be laminated on this flat film. For example, even when the thin films of the alloyed crystal are laminated, it is possible to obtain the flat film on the uppermost layer of the laminated structure as shown in the surface image in FIG. 3 by growing the step structure on the surface of the film while maintaining the above-described conditions.

Meanwhile, the embodiment uses the ZnO-based substrate as the growth substrate for growing the ZnO-based thin film. However, it is also possible to use a GaN substrate or a sapphire substrate having a hexagonal crystal structure instead of the ZnO-based substrate. In this case, it is also possible to form the flat ZnO-based thin film as in the case mentioned above.

Now, a method of manufacturing the ZnO-based thin film as shown in FIG. 1 will be described below. A ZnO substrate having a normal line to a principal surface of the substrate offset by an angle of 0.5 degrees in the direction of the m-axis is used as the ZnO-based substrate 1. This ZnO substrate is put into a load lock chamber and heated at 200° C. for 30 minutes in a vacuum environment in a range from about 1×10⁻⁵ to 1×10⁻⁶ Torr for water removal. The substrate is introduced to a growth chamber having wall surfaces cooled down with liquid nitrogen by way of a conveyor chamber having a vacuum level around 1×10⁻⁹ Torr, and the ZnO-based thin film 2 is grown by use of the MBE method.

Zn is supplied as a Zn molecular beam by using a Knudsen cell prepared by putting high-purity Zn of 7N into a crucible made of pBN and heating and sublimating Zn at a temperature in a range from about 260° C. to 280° C. While Mg is an example of IIA group elements, high-purity Mg of 6N is used as for Mg, which is sublimated from a cell having a similar structure by heating in a range from 300° C. to 400° C. and is supplied as an Mg molecular beam. As for oxygen, O₂ gas of 6N is used and supplied to an RF radical cell provided with a discharge tube having small orifices opened in part of a cylinder at a rate from about 0.1 sccm to 5 sccm through a SUS tube having an electrolytically polished inner surface. Then, plasma is generated by applying an RF high-frequency wave around 100 W to 300 W, so that oxygen is formed into the state of O radical with enhanced reaction activity and supplied as an oxygen source. The plasma is important here, because no ZnO-based thin films are formed by putting O₂ raw gas therein.

A SiC-coated carbon heater is used for typical resistance heating of the substrate. A metallic heater made of W or the like cannot be used because of oxidation. There are also other heating methods such as lamp heating or laser heating. It is possible to use any of those methods as long as the method is oxidation-resistant.

After heating to a temperature of 750° C. or above and heating in a vacuum around 1×10⁻⁹ Torr for about 30 minutes, the growth of the ZnO thin film is started by opening shutters for the radical cell and the Zn cell. At this time, a temperature of 750° C. or above is necessary from the viewpoint of the substrate temperature in order to obtain the flat film as described above irrespective of which type of the film is to be formed.

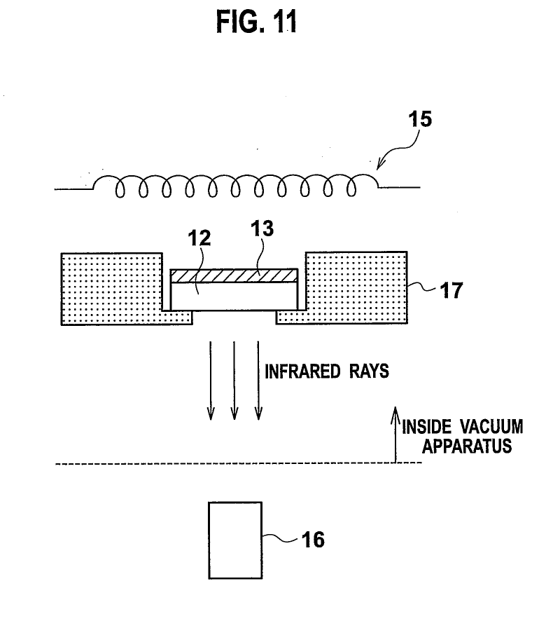

Incidentally, while it is necessary to set the substrate temperature (the growth temperature) at 750° C. or above in order to achieve crystal growth of the flat ZnO-based thin film on the ZnO-based material layer, this substrate temperature needs to be accurately detected. The measurement of the substrate temperature is carried out by using any of configurations shown in FIG. 10 and FIG. 11. Reference numeral 12 denotes a ZnO-based substrate, and a multilayer film 13 is formed on the ZnO-based substrate 12 on an opposite side of a crystal growth surface. The multilayer film 13 includes a laminated body formed by laminating a dielectric film and an Au (gold) film in this order from the ZnO-based substrate 12 side. The dielectric film utilizes NiO, SiO₂ or the like. Here, the multilayer film 13 may include a laminated body formed by laminating a dielectric film and a Pt (platinum) film in this order from the ZnO-based substrate 12 side while using the Pt (platinum) film instead of the Au film. The dielectric film has a role for preventing diffusion of Au or Pt.

Thereafter, in the configuration of FIG. 10, the ZnO-based substrate 12 provided with the multilayer film 13 is fitted to a substrate holder 14 and adjusted to a predetermined growth temperature by applying heat from a heat source 15 such as a heater. The substrate temperature at this time is measured by use of an infrared thermometer (a pyrometer) 16.

Following problems may arise when fitting only the ZnO-based substrate 12 without the multilayer film 13 to the substrate holder 14 and measuring the substrate temperature. A ZnO-based material is almost transparent from a visible light range to a wavelength around 8 μm. Therefore, infrared rays from the substrate holder 14 for use in the crystal growth are transmitted through the ZnO-based substrate 12 or the ZnO-based thin film that is laminated on the ZnO-based substrate 12 in advance. Since these unnecessary infrared rays are incident on the infrared thermometer 16, it is impossible to measure the accurate substrate temperature of the ZnO-based substrate.

Meanwhile, in the configuration of FIG. 11, when fitting only the ZnO-based substrate 12 without the multilayer film 13 to a substrate holder 17 and measuring the substrate temperature, the infrared thermometer 16 does not receive infrared rays from the substrate holder 14 as shown in FIG. 10 because no substrate holder is located on a back surface of the ZnO-based substrate 12. However, the infrared rays from the heat source 15 are transmitted through the ZnO-based substrate 12 or the ZnO-based thin film that is laminated on the ZnO-based substrate 12 in advance, and are incident on the infrared thermometer 16. Accordingly, it is impossible to execute the accurate measurement of the substrate temperature.

Meanwhile, a heat treatment (annealing) after formation of electrodes to fabricate devices or annealing for activating doped impurities may be executed. In this case, it is impossible to measure the accurate temperature due to the same reasons as mentioned above.

Nevertheless, the ZnO-based substrate 12 is provided with the multilayer film 13 in the direction opposite to the direction of lamination of the ZnO-based thin film. Accordingly, the multilayer film 13 is configured to be opposed to the substrate holder 14 in FIG. 10 while the multilayer film 13 is configured to be opposed to the heat source 15 in FIG. 11. Thus, the Au film or the Pt film in the multilayer film 13 reflects the infrared rays emitted from the heat source 15 or the substrate holder 14 and prevents transmission through the ZnO-based substrate 12 or the ZnO-based thin filmed laminated thereon. Consequently, only the infrared radiation from the back metal such as the Au film or the Pt film that indicates the temperature of the substrate itself is incident on the infrared thermometer 16. Hence it is possible to execute the accurate temperature measurement. In this way, the substrate temperature is measured by use of the infrared thermometer 16 and the substrate temperature is regulated to be equal or above 750° C.

Incidentally, it is impossible use a material susceptible to oxidation as the back metal for reflecting the infrared rays because the ZnO-based thin film is formed in an oxidative atmosphere. Therefore, as described above, Pt or Au is appropriate for the metal which is able to resist oxygen and to tolerate the temperature exceeding 750° C. Here, when the Au film is applied to the multilayer film 13, it is preferable to set infrared emissivity of the Au film equal to 0.5. Meanwhile, when the Pt film is applied to the multilayer film 13, it is preferable to set infrared emissivity of the Pt film in a range from 0.3 to 0.15.

Alternatively, it is also possible to apply thermography to the configuration of the substrate temperature measurement shown in FIG. 10 or 11 instead of the pyrometer 16. The pyrometer 16 using InGaAs as a detector utilizes a detection wavelength around several micrometers. Accordingly, it is impossible to measure the substrate temperature accurately in the case of the ZnO-based substrate or the ZnO-based thin film having the high transparency in the infrared range as described previously. For this reason, the multilayer film 13 is provided as described above.

However, the thermography has wavelength sensitivity in a range from about 8 μm to 14 μm, and is therefore able to execute measurement at a room temperature and suitable for the temperature measurement of the ZnO-based substrate, the ZnO-based thin film and the like. As is well known, the thermography is an apparatus capable of analyzing infrared rays emitted from an object and visualizing heat distribution in the form of a chart. When employing the thermography, the infrared radiation emitted from the ZnO-based substrate 12 is analyzed and the heat distribution of the ZnO-based substrate 12 heated by the heat source 15 is measured.

For example, transmittance of infrared rays having a wavelength of 8 μm to transmit through the ZnO-based substrate 12 accounts for several percent. If the ZnO-based substrate 12 is used as a single body without the multilayer film 13 being formed, this substrate appears to be black when observed with the thermography. That is, the infrared rays to be emitted from a certain object located behind the ZnO-based substrate 12 from a viewpoint of the thermography are cut off by the ZnO-based substrate 12, so that the substrate temperature can be accurately measured by the thermography on the basis of the infrared rays emitted from the ZnO-based substrate 12.

Here, when employing the thermography, it is preferable to employ the thermography provided with an infrared detector of a bolometer type. This is because non-cooling type infrared thermography utilizing an infrared detector of a heated type such as a bolometer type or a pyroelectric type can achieve reduction in size, weight and cost as compared to a case of providing an infrared array sensor utilizing a quantum infrared detector that requires cooling.

1. A ZnO-based thin film to be epitaxially grown on a substrate, characterized in that a principal surface in a direction of crystal growth of the ZnO-based thin film is formed to have an arithmetic average roughness of 1.5 nm or below and a square mean roughness of 2 nm or below.

2. A ZnO-based thin film to be epitaxially grown on a substrate, characterized in that a principal surface in a direction of crystal growth of the ZnO-based thin film is formed to have an arithmetic average roughness of 1 nm or below and a square mean roughness of 1.5 nm or below.

3. A ZnO-based thin film to be epitaxially grown on a substrate, characterized in that a step height of a surface step structure included in a principal surface in a direction of crystal growth of the ZnO-based thin film is formed to be equivalent to one monolayer thickness of a ZnO-based crystal.

4. A ZnO-based thin film to be epitaxially grown on a substrate, characterized in that step lines of a surface step structure included in a principal surface in a direction of crystal growth of the ZnO-based thin film are formed substantially perpendicularly to an m-axis.

5. The ZnO-based thin film according to claim 2, characterized in that
the principal surface in the direction of the crystal growth includes a surface step structure, and
a step height of the step structure is formed to be equivalent to one monolayer thickness of a ZnO-based crystal.

6. The ZnO-based thin film according to claim 3, characterized in that
the principal surface in the direction of the crystal growth includes a surface step structure, and
step lines of the step structure are formed substantially perpendicularly to an m-axis.

7. The ZnO-based thin film according to claim 4, characterized in that a fluctuation range of irregularities from straightness of the step lines is formed to be equal to or below an ideal width of a terrace surface included in the step structure relative to almost all of the step lines.

8. A ZnO-based thin film characterized by being epitaxially grown on a substrate at a growth temperature of 750° C. or above.

9. The ZnO-based thin film according to claim 6, characterized in that a fluctuation range of irregularities from straightness of the step lines is formed to be equal to or below an ideal width of a terrace surface included in the step structure relative to almost all of the step lines.

10. The ZnO-based thin film according to claim 1, characterized in that
the principal surface in the direction of the crystal growth includes a surface step structure, and
a step height of the step structure is formed to be equivalent to one monolayer thickness of a ZnO-based crystal.

11. The ZnO-based thin film according to claim 2, characterized in that
the principal surface in the direction of the crystal growth includes a surface step structure, and
step lines of the step structure are formed substantially perpendicularly to an m-axis.

12. The ZnO-based thin film according to claim 1, characterized in that
the principal surface in the direction of the crystal growth includes a surface step structure, and
step lines of the step structure are formed substantially perpendicularly to an m-axis.

13. The ZnO-based thin film according to claim 12, characterized in that a fluctuation range of irregularities from straightness of the step lines is formed to be equal to or below an ideal width of a terrace surface included in the step structure relative to almost all of the step lines.

14. The Zno-based thin film according to claim 11, characterized in that a fluctuation range of irregularities from straightness of the step lines is formed to be equal to or below an ideal width of a terrace surface included in the step structure relative to almost all of the step lines.
